(19) United States
(12) Patent Application Publication
(10) Pub. No.: US 2016/0276528 A1
(43) Pub. Date: Sep. 22, 2016

(54) METHOD FOR MANUFACTURING HETEROSTRUCTURES FOR MIDDLE INFRARED BAND, A HETEROSTRUCTURE, AND A LIGHT-EMITTING DIODE AND A PHOTODIODE BASED THEREON

(71) Applicant: LIMITED LIABILITY COMPANY "LED MICROSENSOR NT", Saint Petersburg (RU)

(72) Inventor: Sergei Sergeevich KIZHAEV, Saint Petersburg (RU)

(21) Appl. No.: 14/659,277

(22) Filed: Mar. 16, 2015

(51) Int. Cl. H01L 33/06; H01L 31/18; H01L 31/0304; H01L 31/109; H01L 33/30; H01L 33/00

(52) U.S. Cl. CPC H01L 33/06; H01L 33/30; H01L 33/0062; H01L 31/0304; H01L 31/109; H01L 31/184

(57) ABSTRACT

The present invention relates to producing spontaneous radiation sources based on A^{III}B^{V} semiconductor compounds in 2.6-4.7 μm spectral range, and to manufacturing photosensitive structures for 2.0-4.7 μm spectral range. In the first embodiment, the heterostructure comprises a substrate containing InAs, a barrier layer containing InSbP and arranged on the substrate, and an active layer containing InAsSbP and arranged on the barrier layer. Light-emitting diodes based on the first embodiment of the heterostructure emit in the range of 2.6-3.1 μm. In the second embodiment, the heterostructure comprises a substrate containing InAs, an active area containing InAsSb and arranged on the substrate, and a barrier layer containing InSbP and arranged on the active area. The active area can comprise a bulk active layer InAsSb, quantum wells InAs/InAsSb or a strained superlattice GaInAs/InAsSb. Light-emitting diodes based on the second embodiment of the heterostructure emit at a wavelength in the range of 3.1-4.7 μm, and photodiodes have broadband sensitivity in 2.0-4.7 μm range. In the embodiment for manufacturing a heterostructure, tert-butylarsine is used as the source of arsenic, and tert-butylphosphine is used as the source of phosphorus.

### FIELD OF THE INVENTION

The present invention relates to producing spontaneous radiation sources based on A^{III}B^{V} semiconductor compounds in 2.6-4.7 μm spectral range, and to manufacturing photosensitive structures for 2.0-4.7 μm spectral range. Light-emitting diodes manufactured based on disclosed heterostructures emit radiation in 2.6-4.7 μm middle infrared range, and photodiodes have broadband photosensitivity in 2.0-4.7 μm range. The disclosed method for manufacturing heterostructures, the light-emitting diode and the photodiode based thereon provide significant advantages in manufacturing sensors configured for gas analysis. In particular, said sensors can be used for monitoring the environment, for technological process control, e.g. for sensing carbon dioxide (absorbing radiation in 2.64-2.87 μm range at wavelength of 4.27 μm) and hydrogen sulfide (absorbing radiation at wavelength of 2.63 μm) in residential and industrial buildings. The 2.6-4.7 μm radiation range includes primary characteristic absorption bands of the CH-group, in particular of such compounds as methane and alcohols. Furthermore, middle infrared band sensors can be used in medical diagnostics, e.g. for light spectroscopy used to analyze concentration of carbon dioxide, acetone and other compounds in exhaled air. Further, the 2.65-2.85 μm range includes primary characteristic absorption bands of water and water vapors. The present invention is not limited to aforementioned examples, and the heterostructure and light-emitting diodes based thereon can be used in any other applications that require sensing presence and/or concentration of compounds with absorption bands in the middle infrared range of 2.6-4.7 μm, and 2.0-4.7 μm range for photodiodes.

### BACKGROUND OF THE INVENTION

Infrared optical sensors based on heat infrared radiation sources are manufactured by Perkin Elmer, Texas Instruments, City Technology and other companies. Such sources emit radiation in a broad spectral range, and then narrowband optical filters isolate the required wavelength range.

The disadvantage of prior art optical sensors is that they require the use of optical filters. Furthermore, prior art optical sensors have other disadvantages, such as high power consumption, low-speed performance, bulky dimensions and limited heat source lifetime.

The above disadvantages of prior art infrared optical sensors based on heat infrared radiation sources can be overcome by using light-emitting diodes and photodiodes operating in middle infrared range.

The technology of manufacturing light-emitting diodes and photodiodes for visible and near infrared spectral bands based on GaN, GaAs and InP is well-developed. Such devices have the internal quantum efficiency values close to 1. However, it is much more difficult to achieve high quantum efficiency in middle infrared range. The internal quantum efficiency values of light-emitting diodes operating in wavelength range about 3 μm is 4 to 5 times lower. Narrow-bandgap compounds based on InAs have a high charge carrier diffusion length (about 25 μm for electrons) and possess lower radiative recombination efficiency and higher intensity of nonradiative processes.

A semiconductor diode for near infrared band (Russian Federation patent No. 2286618, IPC H01L 33/00, H01L 31/12) comprises p and n areas with conductive contacts divided by a p-n junction, an active area electrically connected to the p-n junction, and at least one optical module optically connected to the active area via an optical compound.

The disadvantage of prior art semiconductor diode is the limited wavelength range of 1.22-1.24 μm, in which the prior art diode can emit. The radiation wavelength of the prior art diode is determined by the diode structure, the diode comprises a n⁺-InP substrate with active layer comprising a InGaAsP solid solution grown thereon. In another embodiment, the prior art semiconductor diode comprises a n⁺-InAs substrate with a double heterostructure n-InAsSbP/n-InGaAs-p/p-InAsSbP grown thereon. Said diode emits at a wavelength of 3.4 μm. In yet another embodiment, the prior art semiconductor diode comprises a n-InAs substrate with a double heterostructure n-InAsSbP/n-InGaAsSb/p-InAsSbP grown thereon. Said diode emits at a wavelength of 3.9 μm. Therefore, the above heterostructures cannot be used to obtain diodes emitting in the range of 2.6-3.3 μm. Furthermore, the prior art semiconductor diodes cannot be used to determine presence and/or concentration of compounds (such as water and water vapors, carbon dioxide, hydrogen sulfide) with characteristic absorption bands falling within said range.

Furthermore, the prior art diodes are formed using liquid-phase epitaxy. The disadvantage of liquid-phase epitaxy is the practical complexity in growing heterostructures of small dimensions required to grow bulk layers. Furthermore, liquid-phase epitaxy is unsuitable for growing InAsSbP solid solutions across the whole range of compositions due to the presence of immiscibility regions.

Yet another disadvantage of the prior art diode is the use of an optical module and an optical compound, which complicates the process of diode manufacturing and increases the risk of defects at the process stage of coupling the optical module with the LED chip.

Further, light-emitting diodes based on InAsSbP solid solutions (T. N. Danilova, A. N. Imenkov, K. D. Moiseev, I. N. Timchenko, Yu. P. Yakovlev: “Light-emitting diodes based on InAsSbP for spectral range of 2.6-3.0 μm (T=300K)”; Letters to the Technical Physics Journal, 1994, vol. 20, issue 10, p. 20-24) are known in the art. The structure of the prior art light-emitting diode grown using liquid-phase epitaxy comprises a n-InAs substrate, an n-type wide-band layer containing InAsSbP, a p-type active layer containing InAsSbP, and a p-type wide-band layer containing InAsSbP. The quantum efficiency of radiation emitted by prior art light-emitting diodes does not exceed 0.02-0.03% at room temperature with 50 mA current. Phosphorus content in wide-band areas does not exceed 30%.

The disadvantage of prior art light-emitting diodes is low quantum efficiency.

Further, light-emitting diodes based on InAsSbP solid solutions (V. V. Romanov, E. V. Ivanov, A. N. Imenkov, N. M. Kolchanova, K. D. Moiseev, N. D. Stoyanov, Yu. P. Yakovlev: “Light-emitting diodes based on InAsSbP limiting composition solid solutions for spectral range of 2.6-2.8 μm”; Letters to the Technical Physics Journal, 2001, vol. 27, issue 14, p. 8087) are known in the art. The structures for the prior art light-emitting diodes are grown using liquid-phase epitaxy. The prior art emitting structure comprises a p-InAs substrate with a p-type barrier layer containing InAsSbP, an active layer containing InAsSbP, and an n-type barrier layer containing InAsSbP consequently grown thereon. The spinodal decomposition area and molecularity condition limitation lead to the formation of a large area of InAsSbP solid solution compositions, which is inaccessible for crystallization using near-equilibrium methods, i.e. liquid-phase epitaxy methods, which does not provide conditions for effective charge carrier retention in the active area of the diode. The InP content in barrier layers of prior art light-emitting diodes grown using liquid-phase epitaxy does not exceed 32%, and said value is defined as the theoretical limit, and therefore, when using liquid-phase epitaxy, the light-emitting diode efficiency cannot be increased by increasing barrier height at the heterointerface between the barrier layer and the active layer.

Further, light-emitting diodes with a wavelength of 3.3-3.4 μm (A. P. Astakhova, A. S. Golovin, N. D. Ilyinskaya, K. V. Kalinina, S. S. Kizhaev, O. Yu. Serebrennikova, N. D. Stoyanov, Zs. J. Horvath, Yu. P. Yakovlev: “Powerful light-emitting diodes based on InAs/InAsSbP heterostructures for methane spectroscopy (λ≈3.3 μm)”; Semiconductor physics and technology, 2010, vol. 44, issue 2, p. 278284) are known in the art. The method for manufacturing heterostructures disclosed in the above publication is considered prior art for the present invention. The prior art light-emitting diodes are formed based on a heterostructure comprising a substrate containing InAs, a first barrier layer containing InAsSbP, and an active layer containing InAs. Furthermore, the heterostructure can comprise a second barrier layer containing InAsSbP and arranged between the substrate and the active layer. The heterostructure is formed from organometallic compounds by means of vapor-phase epitaxy. The following compounds are used as epitaxial layer growth sources for the prior art heterostructure: trimethylindium TMIn (source of indium), trimethylstibine TMSb (source of stibium), hydride gases arsine AsH₃ (source of arsenic) and phosphine PH₃ (source of phosphorus). The hydride gases are diluted in hydrogen to 20% concentration. Diethylzinc DeZn is used for doping epitaxial layers with a p-type dopant (zinc).

The disadvantage of the prior art method for manufacturing light-emitting diodes is the use of highly toxic hydride gases arsine and phosphine as sources of arsenic and phosphorus, respectively. Furthermore, reactions involving arsine and phosphine are accompanied by side reactions adversely affecting the composition and properties of grown structure.

Further, the prior art light-emitting diodes have radiation peaks in the limited wavelength range of 3.3-3.4 μm, which significantly limits the number of compounds that can be sensed using prior art light-emitting diodes. Furthermore, the barrier layer of prior art heterostructure does not allow for secure retention of primary charge carriers in the active area, which reduces efficiency of light-emitting diodes and photodiodes.

Therefore, despite the fact that various heterostructures for middle infrared band and light-emitting diodes based thereon are known in the art, there is still a need for heterostructures in which the barrier layer provides secure retention of primary charge carriers in the active area and allows to increase radiative recombination ratio in the active area. Furthermore, the need exists for light-emitting diodes based on such heterostructures that can be manufactured for operation at any wavelength within the 2.6-4.7 μm range, as well as photodiodes for operation at any wavelength within the 2.0-4.7 μm range. Still furthermore, the need exists for a method, according to which such structures are manufactured by means of vapor-phase epitaxy without using toxic hydride gases such as arsine and phosphine.

### SUMMARY OF THE INVENTION

The object of the present invention is to provide a method for manufacturing a heterostructure without the use of toxic and hazardous gases (arsine and phosphine).

Another object of the present invention is to provide a reliable and effective heterostructure providing electron confinement in the active area.

Another object of the present invention is to provide a light-emitting diode based on said heterostructure.

Another object of the present invention is to provide a method for manufacturing the light-emitting diode based on said heterostructure.

Another object of the present invention is to provide a photodiode based on said heterostructure.

Another object of the present invention is to provide a method for manufacturing the photodiode based on said heterostructure.

According to the first aspect of the present invention, the object is achieved by a first embodiment of the method for manufacturing a heterostructure, wherein a barrier layer containing InSbP is grown on a substrate containing InAs by means of vapor-phase epitaxy, an active layer containing InAsSbP is grown on the barrier layer by means of vapor-phase epitaxy, tert-butylarsine is used as the source of arsenic, and tert-butylphosphine is used as the source of phosphorus.

In the second embodiment of the method for manufacturing heterostructures, wherein an active layer containing InAsSb is grown on a substrate containing InAs by means of vapor-phase epitaxy, a barrier layer containing InSbP is grown on the active layer by means of vapor-phase epitaxy, tert-butylarsine is used as the source of arsenic, and tert-butylphosphine is used as the source of phosphorus.

According to the second aspect of the present invention, the object is achieved by that, in the first embodiment, the heterostructure comprises a substrate containing InAs, a barrier layer containing InSbP and arranged on the substrate, and an active layer containing InAsSbP and arranged on the barrier layer.

In the second embodiment, the heterostructure comprises a substrate containing InAs, an active area containing InAsSb and arranged on the substrate, and a barrier layer containing InSbP and arranged on the active area.

Furthermore, according to the second embodiment of the heterostructure, the active area comprises a bulk layer containing InAsSb.

In another embodiment of the heterostructure, the active area comprises quantum wells containing InAs and InAsSb.

In another embodiment of the heterostructure, the active area comprises a strained superlattice containing GalnAs and InAsSb.

According to the third aspect of the present invention, the object is achieved by a light-emitting diode for middle infrared band comprising at least one LED chip formed based on the first embodiment of the heterostructure and comprising a first contact arranged on the substrate side and a second contact arranged on the active layer side.

In the second embodiment, a light-emitting diode for middle infrared band comprises at least one LED chip formed based on the second embodiment of the heterostructure and comprising a first contact arranged on the barrier layer side and a second contact arranged on the substrate side.

In one embodiment of the light-emitting diode, the first contact is continuous, and the second contact is formed with partial surface covering.

In one embodiment of the light-emitting diode, the second contact has a circular or annular shape.

In one embodiment of the light-emitting diode, the contacts comprise a four-layer Cr/Au/Ni/Au system.

In yet another embodiment, a light-emitting diode for middle infrared band comprises at least one LED chip formed based on the first or the second embodiment of the heterostructure and comprising at least two contacts arranged on the side of the light-emitting diode opposite to the emitting side of the light-emitting diode.

According to the fourth aspect of the present invention, the object is achieved by a method for manufacturing a light-emitting diode of the third aspect, wherein the heterostructure of the first or the second embodiment is provided, two contacts are formed on the opposite sides of the heterostructure, and the heterostructure with contacts formed thereon is divided, thus forming LED chips.

In another embodiment of the method for manufacturing a light-emitting diode, wherein the heterostructure of the first embodiment or the heterostructure of the second embodiment is provided, at least two contacts are formed on the substrate side or at least two contacts are formed on the barrier layer side, respectively, and the heterostructure with contacts formed thereon is divided, thus forming LED chips.

According to the fifth aspect of the present invention, the object is achieved by a photodiode for middle infrared band comprising at least one photodiode chip formed based on the second embodiment of the heterostructure and comprising two contacts, one of which is arranged on the substrate side and the other is arranged on the barrier layer side.

In one embodiment of the photodiode, one of the contacts is formed with partial surface covering, and the other contact is continuous.

In one embodiment of the photodiode, one of the contacts has an annular shape.

In one embodiment of the photodiode, the contacts comprise a four-layer Cr/Au/Ni/Au system.

In yet another embodiment, a photodiode for middle infrared band comprises at least one photodiode chip formed based on the second embodiment of the heterostructure and comprising at least two contacts arranged on the side of photodiode opposite to the radiation-receiving side of the photodiode.

According to the sixth aspect of the present invention, the object is achieved by a method for manufacturing a photodiode of the fifth aspect, wherein the heterostructure of the second embodiment is provided, two contacts are formed on the opposite sides of the heterostructure, and the heterostructure with contacts formed thereon is divided, thus forming photodiode chips.

In another embodiment of the method for manufacturing a photodiode of the fifth aspect, wherein the heterostructure of the second embodiment is provided, at least two contacts are formed on the barrier layer side or at least two contacts are formed on the substrate side, and the heterostructure with contacts formed thereon is divided, thus forming photodiode chips.

### Technical Result

The introduction of a barrier layer containing InSbP into the heterostructure composition according to the present invention provides electron confinement at the heterointerface with the active area. As a result, the concentration of charge carriers and defects in the active area is reduced and the Shockley-Read nonradiative recombination ratio is reduced, thus increasing operating efficiency of light-emitting diodes and photodiodes.

Furthermore, the use of tert-butylarsine C₄H₉AsH₂ as the source of arsenic instead of the hydride gas AsH₃ and the use of tert-butylphosphine C₄H₉PH₂ as the source of phosphorus instead of PH₃ [symbol] allows to reduce contamination of the grown layers with impurities, to increase structural perfection of epitaxial structures and to increase safety and environmental friendliness of the heterostructure growth process.

Furthermore, in the first embodiment of the light-emitting diode of the present invention, high efficiency is achieved due to the fact that in said LED structure, the radiation is output through the n-InAsSbP active layer. The output of radiation from the LED structure volume avoiding material with p-type conductivity allows to avoid absorption of radiation by free holes that is significantly stronger than the absorption by free electrons. Furthermore, the disclosed LED structure provides minimal active area temperature during current flow due to the fact that a minimum-resistance contact system has been selected.

Furthermore, in the second embodiment of the light-emitting diode of the present invention, high efficiency is achieved due to the fact that in said LED structure, the radiation is output through the highly-doped n-InAs substrate. The Burstein-Moss effect leads to an increase in Fermi level in the InAs substrate up to 100 meV. The increase in Fermi level in the InAs substrate makes the substrate transparent for radiation generated in the active area volume. Furthermore, the disclosed LED structure provides minimal active area temperature during current flow due to the fact that point contacts are formed on a narrow-band highly doped material (n-InAs), a contact system with minimum resistance is provided, the LED chips are mounted with the epitaxial side directed downwards, thus providing effective heat removal due to the fact that the distance between the p-n junction and the metallic surface does not exceed several micron.

### BRIEF DESCRIPTION OF THE DRAWINGS

FIG. 1 shows energy diagrams of prior art LED structures of two types (a and b);

FIG. 2 shows a scheme of the first embodiment of the heterostructure according to the present invention;

FIG. 3 shows a scheme of the second embodiment of the heterostructure according to the present invention;

FIG. 4 shows a scheme of the epitaxial apparatus for growing structures from organometallic compounds by means of vapor-phase epitaxy;

FIG. 5 shows a diffraction rocking curve of the InAs_{0.27}Sb_{0.23}P_{0.5} solid solution;

FIG. 6 shows a diffraction rocking curve of the InSb_{0.32}P_{0.68} solid solution;

FIG. 7 shows a scheme of contact area arrangement for taking measurements.

The embodiments of the present invention are discussed below with reference to accompanying drawings. Said embodiments are provided by the way of example and are not meant to be limiting. The scope of the invention is defined and limited by the appended claims.

### DETAILED DESCRIPTION OF THE INVENTION

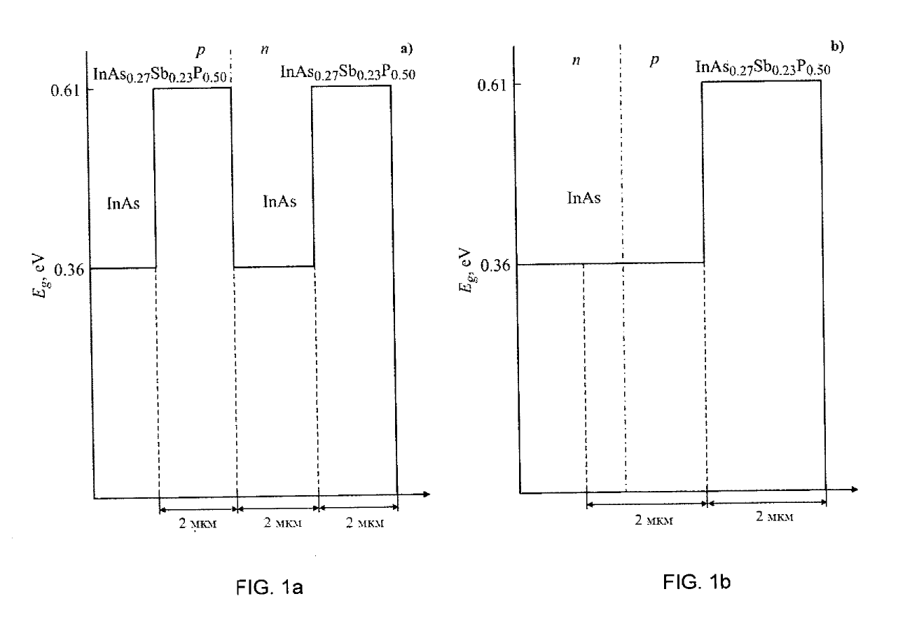

FIG. 1 shows energy diagrams of prior art LED structures. FIG. 1(a) shows a prior art structure of the first type grown on a p-type substrate containing InAs and doped with zinc. The epitaxial part of the structure comprises a barrier layer InAs_{0.27}Sb_{0.23}P_{0.5} doped with zinc, a non-doped active area InAs and a non-doped barrier layer [symbol] InAs_{0.27}Sb_{0.23}P_{0.5}. Epitaxial layers have the following thickness values: active area InAs: 2 μm, lower barrier layer InAsSbP: 1 μm, upper barrier layer InAsSbP: 2 μm. A continuous ohmic contact is formed on the substrate side, and a point contact with a diameter of 100 μm is formed on the epitaxial layer side.

FIG. 1(b) shows a prior art structure of the second type grown on an n-type substrate containing InAs and doped with sulfur. The epitaxial part of the structure comprises a deliberately non-doped layer InAs with 2 μm thickness and a zinc-doped barrier layer InAs_{0.27}Sb_{0.23}P_{0.5} with 2 μm thickness. The p-n junction is arranged in the active area InAs at a distance of 0.5 μm from the interface between the substrate and the epitaxial part of the structure. A continuous contact is applied on the epitaxial layer side, and point contacts with diameters of 100 μm are formed on the substrate side. The LED chips are therefore mounted with the epitaxial side facing downwards.

The light-emitting diode operation can be represented as a sum of processes of non-primary charge carrier diffusion, recombination at the heterointerface between the active area and the barrier layers, radiative and nonradiative recombination in the active area volume, radiation self-absorption in the active area of the diode, and output of the generated radiation from the semiconductor volume. High diffusion length of charge carriers provides significant effect of interface recombination on the operation of the light-emitting diode. The radical interface recombination cannot be reduces by increasing active area thickness, as it leads to an increase in radiation self-absorption in the active area. The overall recombination rate in the active area volume of the diode can be expressed as:

Rₜₒₜ=e(A_{SRH}n+B_{rad}n²+C_{Auger}n³)d, wherein

n is the concentration of charge carriers in the active area, e is the electron charge, and d is the active area thickness. The overall recombination includes the Shockley-Read nonradiative process (A_{SRH}n), the radiative recombination (B_{rad}n²) and the nonradiative Auger recombination (C_{Auger}n³). It follows from the above equation that the Shockley-Read nonradiative recombination proportional to n is prevalent at low injection levels. The nonradiative Auger recombination proportional to n³ is prevalent at high injection levels. Light-emitting diodes based on InAs operate according to modes wherein the density of injected carriers is comparable to charge carrier concentration in deliberately non-doped material, and amounts to about 10¹⁶ cm⁻³. The Shockley-Read recombination caused by contaminates and defects in the structure therefore constitutes an important barrier to increasing efficiency of light-emitting diodes, and must be minimized.

In order to improve structural perfection of epitaxial structures, to reduce the probability of Shockley-Read nonradiative processes and to increase quantum efficiency of radiative recombination of light-emitting diodes of the present invention, a heterostructure is disclosed, wherein the barrier layer contains InSbP.

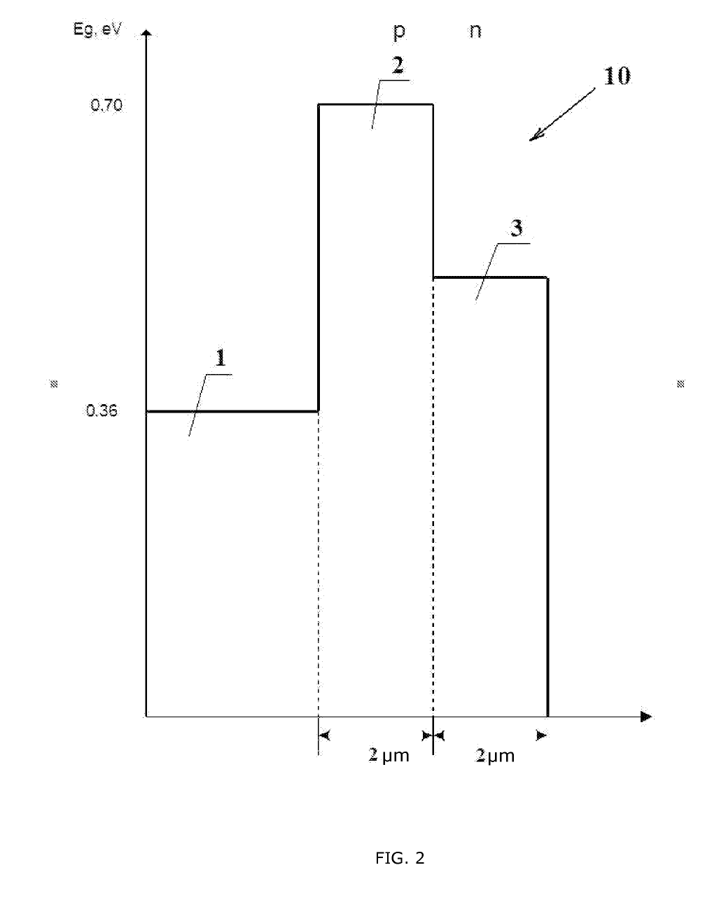

FIG. 2 shows a scheme of the first embodiment of the heterostructure according to the present invention. Heterostructure 10 comprises a substrate 1 containing InAs and doped with zinc with p-charge carrier concentration of about 2*10¹⁸ cm⁻³, a barrier layer 2 arranged on the substrate 1, containing InSb_{1-z}P_{z} and doped with zinc with p-charge carrier concentration up to about 1−3*10¹⁸ cm⁻³, an active layer 3 arranged on the barrier layer 2, having thickness of about 2 μm, containing InAs_{1-x-y}SbₓP_{y} and deliberately non-doped with n-charge carrier concentration of about 2-4*1 0¹⁷ cm⁻³. InP content in the barrier layer 2 is about 68%, and InSb content in the barrier layer 2 is about 32%. The radiation wavelength of the light-emitting diode and the isoperiodicity requirement between the layers of epitaxial structure and the substrate define the required InP and InSb content in the InAsSbP solid solution. Correlation of diffraction rocking curves of the samples and measurement data of elemental composition of InAs_{1-x-y}SbₓP_{y} solid solutions shows that the alignment of lattice parameters of InAs_{1-x-y}SbₓP_{y} layer and InAs substrate occurs in the event when the ratio between mole fractions of InP and InSb in the solid phase is y/x=2.1. Mole fractions of InP and InSb in the active layer are adjusted depending on light-emitting diode wavelength, and for the wavelength of about 2.6 μm, the mole fractions are y=25%, x=12%, respectively. As radiation wavelength increases, the fraction of InP and InSb decreases. For the wavelength of about 3.0 μm, the mole fractions are y=11%, x=5%, respectively. In the utilized structures, the error ratio of lattice parameters of the barrier layer 2 containing InSbP and of the active layer 3 containing InAsSbP amounts to Δa/a less than 2*10⁻⁴. The barrier layer 2 containing InSbP promotes a more secure retention of charge carriers within the volume of the active area of heterostructure 10, while also minimizing nonradiative processes in the active area, compared to the barrier layer InAsSbP in prior art heterostructures. The heterostructure 10 shown in FIG. 2 is used for manufacturing light-emitting diodes operating in the wavelength range of 2.6-3.1 μm.

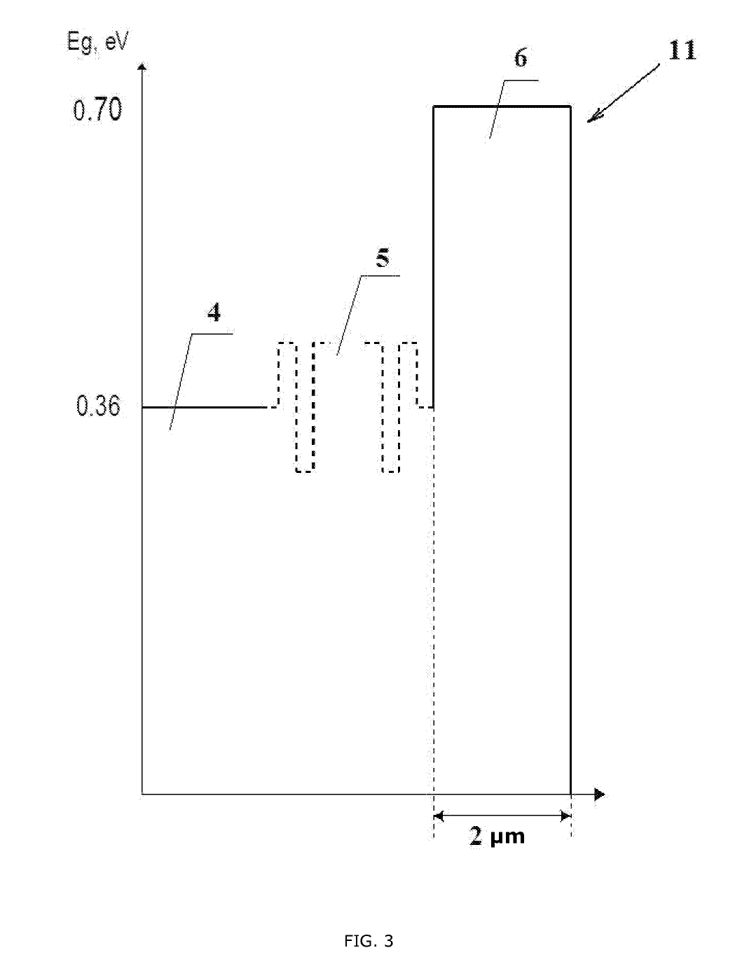

FIG. 3 shows a scheme of the second embodiment of the heterostructure according to the present invention. Heterostructure 11 comprises a substrate 4 containing InAs and doped with sulfur with n-charge carrier concentration of about 2*10¹⁸ cm⁻³, a deliberately non-doped active area 5 arranged on the substrate 4 and having thickness of about 2 μm, and a barrier layer 6 arranged on the active area 5, containing InSbP and doped with zinc to a p-concentration of about 1−3*10¹⁸ cm⁻³. InP content in the barrier layer 6 is about 68%, and InSb content in the barrier layer 6 is about 32%. In one embodiment of the heterostructure 11, the active area 5 comprises a bulk layer containing InAsSb with the mole fraction of InSb in the active area up to 15%. In yet another embodiment of the heterostructure 11, the active area 5 comprises quantum wells InAs/InAsSb. The quantum well is formed by a thin flat layer of semiconductive material (generally with thickness of 1-10 nm), wherein the potential energy of an electron is lower than outside the well; therefore, electron movement is limited in one dimension. According to the laws of quantum mechanics, electron energy in such well is quantized, i.e. can only assume particular discrete values. In yet another embodiment of the heterostructure 11, the active area 5 comprises strained superlattices GalnAs/InAsSb. Thickness of the bulk layer InAsSb in the active area is about 2.5 μm. In the case of using alternating quantized layers InAs/InAsSb or GalnAs/InAsSb in the active area, the thickness of each layer is, for example, 10 nm, and the overall number of periods is about 108. Due to zinc diffusion into the epitaxial structure during InSbP layer growth, the p-n junction is located in the active area at a distance of 0.3 μm from the interface between the InAs substrate and the epitaxial part of the structure. The disclosed heterostructure 11 allows to increase quantum efficiency of radiative recombination by 20% compared to samples based on prior art voluminous heterostructure InAs/InAsSbP, and further allows to create photodiodes with high ampere-watt sensitivity values. Furthermore, the barrier layer 6 containing InSbP promotes a more secure retention of charge carriers within the volume of the active area 5 of heterostructure 11, while also minimizing nonradiative processes in the active area 5, compared to the barrier layer InAsSbP in prior art heterostructures. The use of quantum wells InAs/InAsSb and strained superlattices GalnAs/InAsSb alleviates the problem of epitaxial dislocation occurrences compared to voluminous structures. Quantized structures further allow to decrease the occurrence of nonradiative Auger processes. In order to produce a heterostructure operating at the 3.4 μm wavelength, an InAsSb bulk layer is formed with a mole fraction of InSb of about 0% in the active area. The 3.2 μm wavelength can be obtained by using a GalnAs/InAs superlattice. Further, the second embodiment of the heterostructure allows to obtain the same wavelength using different methods. For example, the wavelength of 4.4 μm can be obtained by an active area formed as a bulk layer InAsSb with mole fraction of InSb about 8.5%, or by an active area formed as quantum wells InAs/InAsSb (with well thickness of about 10 nm) with mole fraction of InSb about 11%. The heterostructure 11 shown in FIG. 3 according to the present invention is used for manufacturing light-emitting diodes operating in the wavelength range of 3.1-4.7 μm and photodiodes operating in the wavelength range of 2.0-4.7 μm. Further, photodiodes based on the second embodiment of the heterostructure also operate at shorter wavelengths.

Furthermore, according to the present invention, width of forbidden gap Eg of the barrier layer 2, 6 containing InSbP is 0.7 eV, as shown in FIGS. 2 and 3, respectively, and exceeds the width of forbidden gap of the barrier layer InAsSbP of the prior art heterostructure (0.61 eV) according to FIG. 1. Therefore, the electron confinement in the active area of the diode is improved.

The first or the second embodiment of the heterostructure can be selected according to the wavelength, at which the light-emitting diodes and photodiodes of the present invention should operate. The selection of the second embodiment of the heterostructure for manufacturing light-emitting diodes operating in the spectral range of 3.1-4.7 μm is determined due to the following considerations. The wavelength of 3.1 μm is an approximate boundary for allowing radiation output through the substrate InAs. In the highly-doped substrate n-InAs, due to the Burstein-Moss effect, the increase in Fermi level can reach 100 meV, which makes the substrate transparent for radiation with the wavelength of at least 3.1 μm. The substrate transparency allows to apply a continuous cpmtacy on the grown layers side during photolithography of epitaxial structures and to mount light-emitting diodes with epitaxial side facing downwards. Said mounting method significantly improves heat removal, as the p-n junction is arranged at a distance of several micron from the holder, i.e., providing minimal local temperature in the active area during current flow. It is not possible to select an active area composition that would be isoperiodic to InAs substrates for light-emitting diodes with wavelengths over 3.3-3.4 μm. Bulk layers non-isoperiodic to the InAs substrate, strain-alleviating quantum wells or strain-compensating superlattices can be used in the active area.

Furthermore, heterostructures of the present invention are not limited to the use of aforementioned compounds as doping additions; any other doping additions providing the required charge carrier concentration in the layer can also be used.

The heterostructure of the present invention is manufactured by a method utilizing vapor-phase epitaxy from organometallic compounds. Furthermore, those skilled in the art can manufacture the disclosed embodiments of heterostructures using any equipment for vapor-phase epitaxy. It should be noted that the method is not limited to vapor-phase epitaxy, and the heterostructures can also be manufactured using methods of molecular-beam epitaxy, liquid-phase epitaxy or using any other method suitable for manufacturing heterostructures with the structure according to the present invention. It also should be noted that, according to the present invention, the use of the vapor-phase epitaxy from organometallic compounds is preferable.

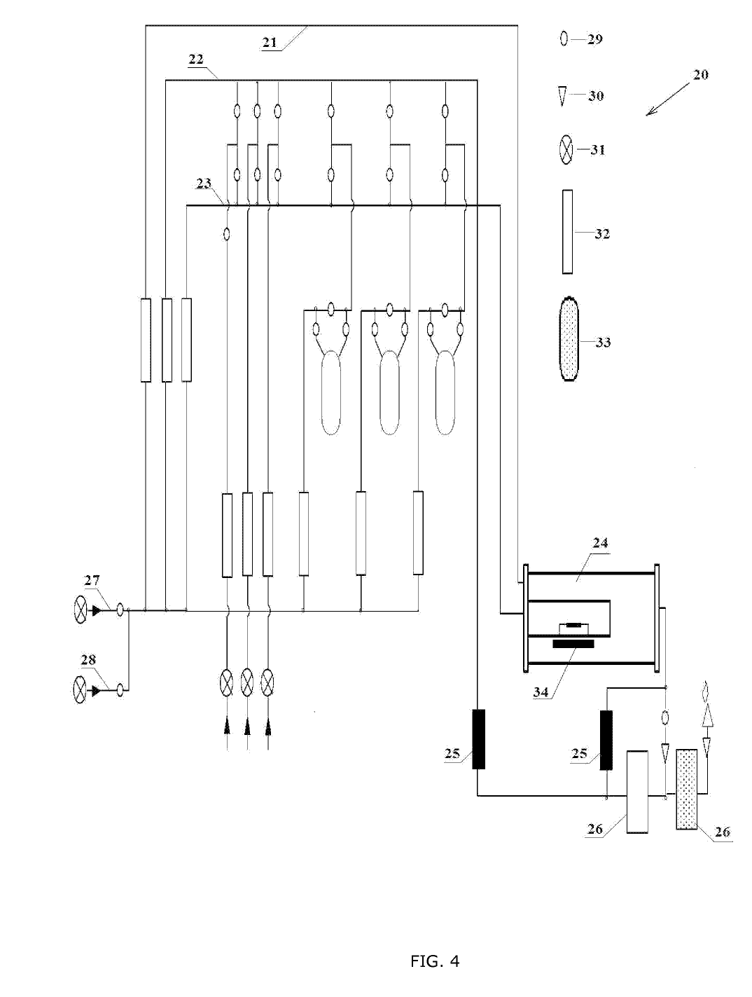

FIG. 4 shows a scheme of the epitaxial apparatus 20 for growing structures from organometallic compounds by means of vapor-phase epitaxy (OMC VPE). The apparatus 20 comprises a gas flow control system (not shown), a purging like 21, a dump line 22, a primary line 23, a reaction chamber 24, a heater 34 for heating the substrate, and a toxic waste disposal system comprising afterburners 25 and filters 26. FIG. 4 shows a hydrogen supply line 27 and a nitrogen supply line 28. Further, FIG. 4 shows vessels 33 with organometallic compounds, gas regulators 32, valves 31, reservoirs 30 and shutters 29. The gas system necessary for preparing and supplying a vapor-gas mixture into the reaction chamber 24 consists of vessels 33 with organometallic compounds, thermostatic ovens (not shown) for maintaining organometallic compounds at a set temperature, gas regulators 32, shutters 29 and valves 31 for highly purified media. Gas regulators 32 are installed in primary hydrogen supply lines 27 and in lines leading to feeders (vessels 33 with organometallic compounds). Gas regulators 32 are formed as a system of automatic gas flow rate control with an electric output signal with voltage of 0 to 10 V proportional to the gas flow rate. Feeders also constitute a part of the gas system. The operational principle of the feeder is based on hydrogen forming a complex vapor-gas mixture when passing through a layer of liquid or powder. The mixture composition is controlled by the flow of hydrogen passing therethrough and by the temperature of the organometallic compound. The organometallic components are mixed in the reaction chamber 24 at atmospheric pressure or at slightly lowered pressure (about 150 mmHg).

Organometallic compounds (OMC) are a wide class of substances containing metal-carbon bonds and coordination compounds of metals with organic molecules.

Organometallic compounds relevant for growing semiconductor film are usually liquid at room temperature, although some compounds remain solid at room temperature and even at higher temperatures. Organometallic compounds usually have a relatively high vapor pressure, and can be easily supplied to the reactor 24 by passing a carrier gas, e.g. nitrogen, hydrogen, argon or helium, through the liquid or over the solid compound functioning as the source.

According to OMC VPE technology, crystallization on the substrate surface occurs as a result of thermal decomposition and interaction between components in the vapor phase. The monocrystalline substrate is placed on the heated holder. Gas mixture adjacent to the substrate surface is heated to high temperatures, whereas the walls of the reaction chamber 24 remain relatively cool, which leads to condensation of the semiconductor film on the crystalline substrate with low reagent loss on the surface of reaction chamber 24. Parameters of the gas mixture can be controlled using an electronic system controlling flow rate from each source.

Growth of layers of the heterostructure of the present invention is the result of decomposition of individual molecules containing elements of the third and fifth periods. The gas flow dynamics in the reactor at atmospheric or near-atmospheric pressure leads to formation of a boundary layer near the static surface of the substrate. Reagent decomposition occurs in the hot boundary layer, through which the molecules pass towards the substrate, or on the surface of the substrate itself. Boundary layer thickness increases in the direction of the flow. The incoming gas mixture contains reagents at higher concentrations than those present in case of equilibrium with the substrate at growth temperature, i.e., the gas is strongly oversaturated, but equilibrium is formed at the interface between the gas and the solid body. Reagents diffusing through the boundary layer decompose, releasing atoms of substances required for layer growth. When diffusion rate through the boundary layer exceeds reagent decomposition rate, the kinetics of surface processes notably affects film growth.

Doping of the growing epitaxial layer in OMC VPE is performed by introducing the corresponding reagent to the gas flow. The reagent is diffused through the boundary layer similarly to the primary reagents forming the layer. The introduction of additions to the crystal lattice can be defined by surface reactions such as adsorption-desorption or surface catalysis, or by reagent thermochemistry. Zinc and magnesium are generally used for doping compounds A³B⁵ with p-type additions, and organometallic reagents based on tellurium, stannum or selenium are generally used for doping with n-type additions. Hydrides (e.g. H₂Se, SiH₄) can also be used for doping epitaxial layers.

The OMC VPE method can provide structures with uniform thickness on large-area substrates. The method can be used for synthesizing film with thickness of several atomic layers.

The method for forming heterostructures of the present invention utilizes the following parent materials: trimethylindium (TMIn) as the source of indium, trimethylstibine (TMSb) as the source of stibium, trimethylgallium (TMGa) as the source of gallium, tert-butylarsine (C₄H₉AsH₂) as the source of arsenic, tert-butylphosphine (C₄H₉PH₂) as the source of phosphorus, and diethylzinc (DeZn) as the source of doping addition (zinc).

In prior art method for forming structures, hydride gases are used, such as arsine (AsH₃) as the source of arsenic and phosphine (PH₃) as the source of phosphorus. Arsine (AsH₃) and phosphine (PH₃) are the most commonly used sources of arsenic and phosphorus in OMC VPE technology, despite their high toxicity and tendency to enter side reactions. Certain difficulties when working with gas tanks containing pressurized toxic gas are thus inevitable. Organometallic compounds are substantially less dangerous in operation, and can be arranged in stainless stell barrels at atmospheric pressure.

The tendency of hydrides to enter side reactions mentioned above causes significant difficulties in arranging reproducible production of layers of In-containing compounds. Growing an InAs reaction in a gas mixture containing TMIn and AsH₃ leads to the formation of an unstable compound InR₃PH₃, wherein R is an alkyl, said compound spontaneously decomposing with the formation of involatile polymer (InRPH)ₙ and CH₄ gas. The polymer precipitates at the approach to the growth zone in the reactor, causing loss in growth efficiency and loss in uniformity of the epitaxial layer. Furthermore, reactor inlet walls operate as a catalyzer of adduct decomposition, and therefore, decomposition rate is sensitive to small changes in surface texture. As a result, the process can perform differently in different systems, or even in one system at different times. InAs grown in such manner is characterized by low and unstable quality with respect to electrical properties and morphology.

In order to improve structural perfection of epitaxial layers in accordance with the method for producing a heterostructure of the present embodiment, replacement of hydride gases arsine and phosphine with alternative sources of arsenic and phosphorus is proposed. Various organometallic compounds, such as trimethylarsine (TMAs), tert-butylarsine (TBAs), phenylarsine (PhAs), monoethylarsine (MEAS) and tert-butylphosphine (TBP) can be used to replace arsine and phosphine in OMC VPE.

Organometallic compounds are also sources of contaminants that can integrate into the epitaxial layer and affect electrical properties, concentration and mobility of charge carriers. The effect of undesirable contaminants is reduced by improving organometallic compound production and purification technology. Carbon is a natural contaminant as part of products of incomplete decomposition of In-containing organometallic compounds (In-CHₓ radicals).

The level of carbon contamination of the epitaxial layer is defined by the ratio of radicals AsHₓ and As reaching the surface. As-H₂ and As-H radicals are products of arsenic source decomposition and decrease carbon contamination of the epitaxial layer due to the fact that said radicals bond with In-CHₓ compounds (products of incomplete decomposition of In-containing OMCs), not allowing them to integrate into the layer being grown.

The use of tert-butylarsine C₄H₉AsH₂ instead of hydride gas AsH₃ as the source of As, and the use of tert-butylphosphine C₄H₉PH₂ instead of PH₃ as the source of P allows to decrease integration of carbon radicals into the layer being grown. Despite the fact that tert-butylarsine and tert-butylphosphine are organometallic compounds, and therefore introduce additional carbon into the vapor phase, reactions above the substrate lead to mutual neutralization of carbon radicals and to a decrease in epitaxial layer contamination. As a result of using the method for forming heterostructures of the present invention, the concentration of charge carriers and defects in the active area is reduced and the Shockley-Read nonradiative recombination ratio is reduced, thus increasing operating efficiency of light-emitting diodes and photodiodes.

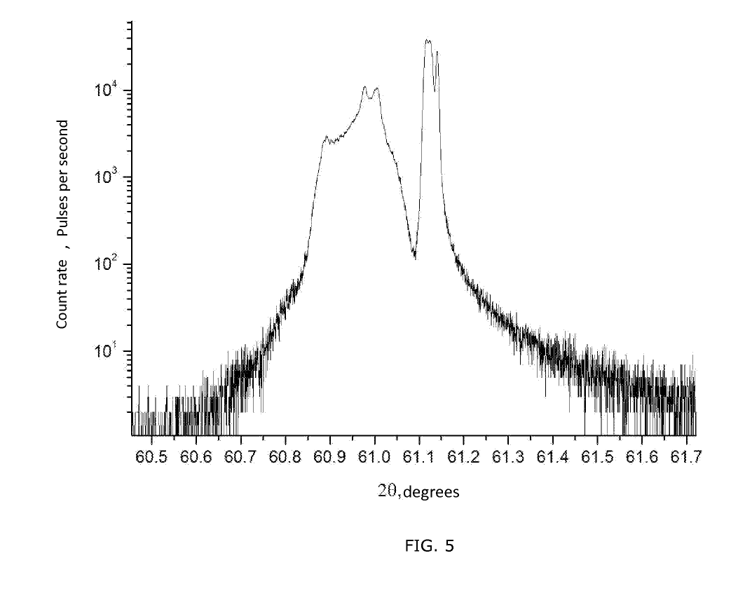

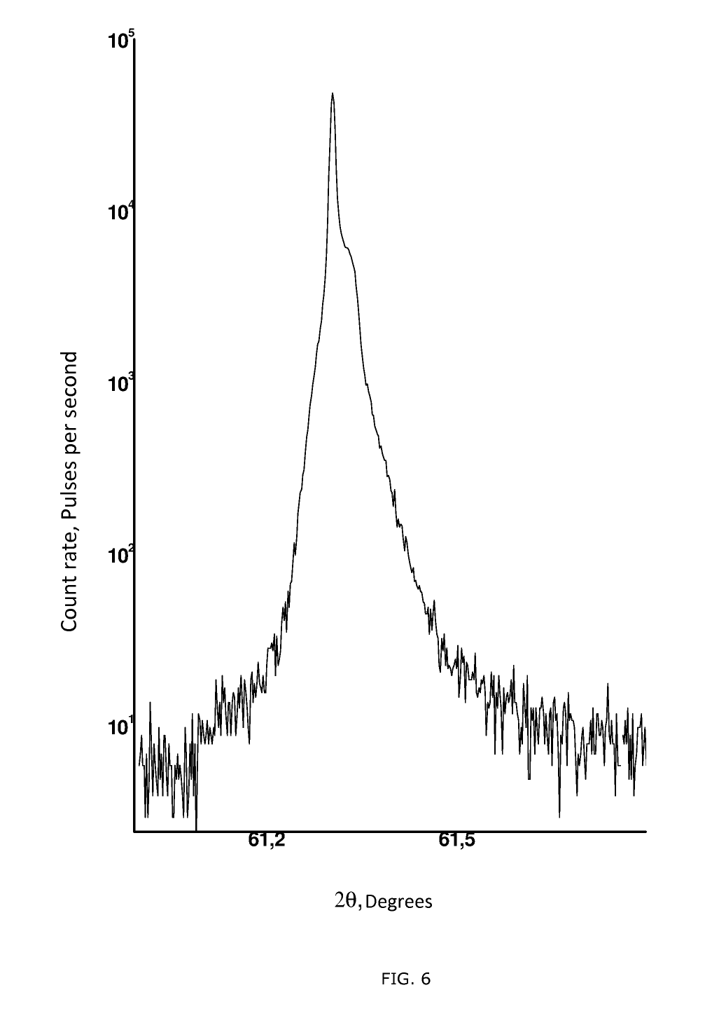

FIGS. 5 and 6 respectively show diffraction rocking curves of prior art InAs_{0.27}Sb_{0.23}P_{0.5} solid solution grown using hydride sources on InAs substrate (100), and the InSID_{0.32}P_{0.68} barrier layer of the present invention also grown on InAs substrate (100), but using tert-butylarsine and tert-butylphosphine. Several peaks on the diffraction rocking curve of examples shown in FIG. 5 and grown using hydrides is probably attributed to decomposition of InAsSbP solid solutions into individual phases. FIG. 6 shows a diffraction rocking curve with a single narrow and prominent peak. Therefore, the improvement in structural perfection of epitaxial layers in case of using organometallic sources of As and P (tert-butylarsine and tert-butylphosphine) is evident. The improvement in structural perfection of epitaxial structures lowers the rate of occurrence of Shockley-Read nonradiative processes and increases quantum efficiency of radiative recombination of light-emitting diodes.

The method for forming heterostructures of the present invention by means of vapor-phase epitaxy includes the following preliminary steps: loading the substrate ready for epitaxy (epi-ready) into the reaction chamber 24, purging the reaction chamber 24 with neutral gas (nitrogen) over 20 minutes, supplying hydrogen into the reaction chamber 24, exhaustion of the reaction chamber 24 (said procedure is carried out in order to ensure that the reaction chamber 24 is hermetically sealed), turning off the pump and supplying hydrogen to the reaction chamber 24, measuring the hydrogen dew point over 2 minutes (said procedure is carried out in order to test purity of the hydrogen carrier gas and to ensure that that couplings of the gas distribution system are hermetically sealed), heating the substrate to 350° C. and removal of oxide film from the substrate surface over 5 minutes, supplying tert-butylarsine into the reactor, heating the substrate to 600° C. under the flow of tert-butylarsine and annealing for 5 minutes (over the course of said step, the substrate surface is additionally cleaned), and cooling the substrate to the temperature of epitaxial structure growth (530° C.).

In order to grow the first embodiment of the heterostructure of the present invention on substrate 1 containing InAs, a barrier layer 2 containing InSbP is grown. In order to grow the barrier layer 2, trimethylindium, trimethylstibine, tert-buthylphosphine and diethylzinc are supplied to the reaction chamber 24 by means of a carrier gas. When the barrier layer 2 thickness reaches about 1-2 μm, the gas supply is stopped. The reaction chamber 24 is purged with hydrogen. In order to grow an active layer 3 containing InAsSbP on the barrier layer 2, trimethylindium, tert-butylarsine, trimethylstibine, and tert-butylphosphine are supplied to the reaction chamber 24 by means of a carrier gas. When the active layer 3 thickness reaches 2 μm, the gas supply is stopped with the exception of tert-buthylarsine and tert-buthylphosphine. The grown structure is cooled to 400° C. under the flow of tert-buthylarsine and tert-buthylphosphine. Upon reaching 400° C., the supply of tert-buthylarsine and tert-buthylphosphine is stopped, and further cooling of the grown heterostructure to room temperature is carried out under the flow of hydrogen. The reaction chamber 24 is unloaded after purging with neutral gas, e.g., nitrogen, over 20 minutes.

In order to grow the second embodiment of the heterostructure of the present invention on substrate 4 containing InAs and doped with sulfur, an active area 5 is grown. In one embodiment, the active area 5 is a bulk active layer containing InAsSb. In order to grow said active layer, trimethylindium, tert-buthylarsene and trimethylstibine are supplied to the reaction chamber 24 by means of a carrier gas.

In yet another embodiment, the active area 5 comprises quantum wells InAs/InAsSb. In order to grow layers forming said quantum wells, trimethylindium and tert-buthylarsene (with discrete supply of trimethylstibine) are supplied to the reaction chamber 24 by means of a carrier gas. Trimethylstibine is supplied for 15 seconds, and then the supply is stopped for 30 seconds.

In yet another embodiment, the active area 5 comprises a strained superlattice GalnAs/InAsSb. In order to grow said superlattice, trimethylindium and tert-buthylarsene (with alternating supply of trimethylgallium and trimethylstibine) are supplied to the reaction chamber 24 by means of a carrier gas. Trimethylgallium is supplied for 30 seconds, then the supply is stopped, and simultaneously with stopping the supply of trimethylgallium, trimethylstibine is supplied for 15 seconds.

When the active area 5 thickness reaches about 1-2 μm, the gas supply is stopped with the exception of tert-buthylarsine. The reaction chamber 24 is purged with hydrogen. In order to grow a barrier layer 6 containing InSbP on the active area 5, trimethylindium, trimethylstibine, tert-buthylphosphine and diethylzinc are supplied to the reaction chamber 24 by means of a carrier gas. When the barrier layer 6 thickness reaches 2 μm, the gas supply is stopped with the exception of tert-buthylarsine and ten-buthylphosphine. The grown structure is cooled to 400° C. under the flow of tert-buthylarsine and tert-buthylphosphine. Upon reaching 400° C., the supply of tert-buthylarsine and tert-buthylphosphine is stopped, and further cooling of the grown structure to room temperature is carried out under the flow of hydrogen. The reaction chamber 24 is unloaded after purging with neutral gas (nitrogen) over 20 minutes.

The gas supply intervals, and subsequently, the growth time required to obtain a layer of specific thickness can be determined empirically. In case when the vapor-phase epitaxy equipment allows to control layer thickness in real time, and therefore to control growth time by any known means, the empirically acquired time value can be recorded as preliminary value.

In order to form a LED chip or a photodiode chip, post-growth processing of heterostructures is performed, said process including photolitographic processes and processes of forming ohmic contacts.

Forming ohmic contacts for the epitaxial structure is part of the technological process of manufacturing a semiconductor device, e.g. a light-emitting diode or a photodiode. Ohmic contacts provide electrical connection between the diode and the external circuit. The contact between metal and semiconductor is ohmic if it is non-rectifying, i.e., the contact resistance is constant upon change in current direction, and if it has a linear voltage-current characteristic, i.e., the contact resistance does not depend on current flow value. Ohmic contacts must meet the following requirements. The contact must have low resistance in directions perpendicular and parallel to the plane of p-n junction; it must not inject non-primary charge carriers; and it must not penetrate the semiconductor deeply. The material used to manufacture the contact must form a stable physical and chemical system with the semiconductor; it must have high thermal conductivity; it must be neutral with respect to the semiconductor or must comprise an addition of the same type as the additions contained in the semiconductor (a donor for the electron semiconductor and an acceptor for the hole semiconductor); and it must provide high mechanical strength to the contact. Meeting the above requirements defines electrical properties of the devices and operational stability thereof in the wide range of operational conditions.

It should be noted that it is virtually impossible to manufacture a contact meeting all requirements set hereinabove. The reason for that lies in innate contradictions of the requirements: the contact between metal and semiconductor must be secure, but metal should not penetrate deeply into the epitaxial structure; the contact material must be neutral, and at the same time must be configured to reduce the oxide film of the semiconductor, as without said reduction, a satisfactory contact resistance cannot be achieved.

In order to produce high-quality contacts, multilayer systems can be advantageously used. A possible example of such system is the Cr (80 Å)—Au (300 Å)—Ni (500 Å)—Au (1000 Å) contact that can be formed on heterostructures of the present invention. The first layer of chrome contacting the semiconductor provides low penetration depth of the contact into the epitaxial structure, reduces oxide films and provides good adhesion with the following gold layer applied thereon. Said chrome and gold layers form the main part of the contact system. As a chemically neutral metal with high conductivity, gold is used for forming the final upper conductive layer. The use of nickel film is necessary in order to prevent interaction between the contact layer and the conductive layer and to reduce diffusion of gold into the structure.

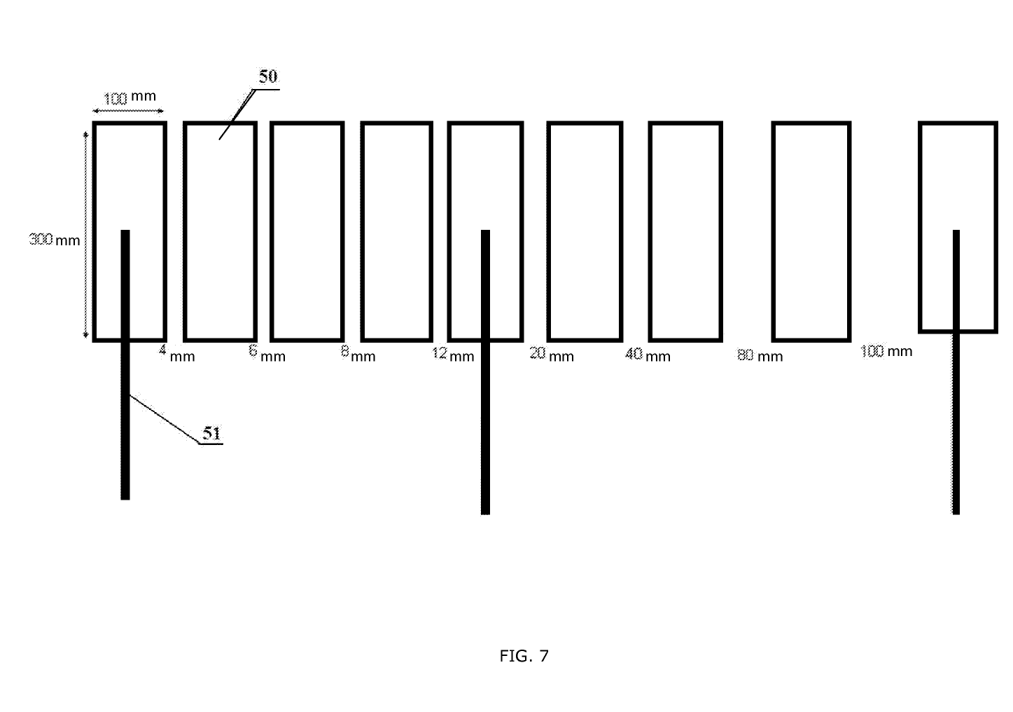

Ohmic contacts must have low resistance in order to reduce heat released upon passing electrical current therethrough. Various contact systems were studied with regards to the following materials: deliberately non-doped epitaxial layers n-InAs₃₂ with electron concentration of about 2*10¹⁶ cm⁻³, n-InAs_{0.53}Sb_{0.15}P_{0.32} with electron concentration of about 1.3*10¹⁷ cm⁻³, p-InAs substrates with hole concentration of about 5*10¹⁸ cm⁻³, and zinc-doped epitaxial layers p-InAs_{0.53}Sb_{0.15}P_{0.32} with hole concentration of about 2*10¹⁸ cm⁻³. As shown in FIG. 7, contact pads 50 sized 300*100 μm², are manufactured for the selected materials and arranged sequentially with an interval of 4 to 100 mm. Driving elements 51 are welded to various contact pads 50 by means of ball bonding. Furthermore, the contacts are subjected to a pull-test. The contact system resistance was measured depending on the distance between contacts. A straight line passed through empirical points separated the value equal to doubled resistance of the contact pad on the vertical axis. The depth resistance of semiconductors selected for measurements was found to be negligible in comparison to contact resistance. Results of the contact system firing study are shown in Tables 1-4. Table 1 lists resistance of contacts coupled to p-InAs substrate (100) with hole concentration of about 5*10¹⁸ cm⁻³. Table 2 lists resistance of contacts coupled to p-InAs_{0.53}Sb_{0.15}P_{0.32} layer with hole concentration of about 2*10¹⁸ cm⁻³. Table 3 lists resistance of contacts coupled to n-InAs epitaxial layer with electron concentration in the layer of about 1*10¹⁶ cm⁻³. Table 4 lists resistance of contacts coupled to n-InAs_{0.53}Sb_{0.15}P_{0.32} epitaxial layer with electron concentration of about 1.3*10¹⁷cm⁻³.

TABLE 1

| | Resistance, ohm | | | | |
|---|---|---|---|---|---|
| | Firing temperature, ° C. | | | | |
| Contact systems | No firing | 250 | 300 | 350 | 400 |
| Cr—AuZn(25%)—Ni—Au | 0.3 | 0.3 | 0.3 | 0.3 | 0.4 |
| Cr—AuZn(5%)—Ni—Au | 5 | 0.4 | 0.7 | 0.4 | |
| AuZn (5%) | 0.7 | 0.7 | | | |

TABLE 2

| | Resistance, ohm | | | | |
|---|---|---|---|---|---|
| | Firing temperature, ° C. | | | | |
| Contact systems | No firing | 250 | 300 | 350 | 400 |
| Cr—AuZn(25%)—Ni—Au | 1.1 | 0.9 | 0.4 | 0.3 | 0.25 |
| Cr—AuZn(5%)—Ni—Au | 1.2 | 0.18 | 0.22 | 0.18 | |

TABLE 3

| | Resistance, ohm | | | | |
|---|---|---|---|---|---|
| | Firing temperature, ° C. | | | | |
| Contact systems | No firing | 250 | 300 | 350 | 400 |
| Cr—Au—Ni—Au | 23 | 0.5 | 0.4 | 0.3 | 0.4 |
| AuGe(12%)—Ni | 3.5 | 0.4 | 0.7 | 0.4 | |
| AuGe(1%)—Ni—Au | 3.5 | 3.2 | 1.6 | 2.5 | |
| AuTe(5%) | 3.5 | 4.5 | 3.5 | 3.2 | |
| AuTe—Ni—Au | 1.4 | 1 | 0.7 | 0.7 | |

TABLE 4

Resistance,
ohm
Firing
temperature,
° C.

| Contact system | No firing | 250 |
|---|---|---|
| Cr—Au—Ni—Au | 3.5 | 9 |

The analysis of measurement results indicates high quality of contacts coupled to highly-doped materials p-InAs and p-InAsSbP. Out of the studied materials, the minimal contact resistance with deliberately non-doped layer of indium arsenide (electron concentration about 2*10¹⁶ cm⁻³) is provided by the contact system Cr—Au—Ni—Au. The resistance value shown (calculated as contact resistance by area thereof) is about 1*10⁻⁴ohm* cm² in the optimal firing mode.

The process of manufacturing a LED chip or a photodiode chip based on the epitaxial structure with Cr—Au—Ni—Au contacts includes the following steps. The heterostructure is processed in acetone, degreased in tetrachloromethane and isopropyl alcohol, and then fired at 130° C. for 30 minutes.

Then photolitography is performed in order to form the first contact. Despite the fact that in this embodiment, the first contact has a circular or annular shape, the first contact can also be formed by a frame having a rectangular, ovoid or any other shape; it can also be formed in the shape of dots, crosses or any continuous geometrical shape without departing from the scope of the present invention. Photolitography includes the following steps: applying a photoresist, applying a “contacts” pattern, exposure, development and hardening at 100° C. for 1 hour. Then, prior to contact coating, the surface is cleaned, e.g. by processing in plasma. The Cr (80 Å)—Au (300 Å)—Ni (500 Å)—Au (1000 Å) contact is then coated on (thickness of each layer indicated in parentheses). After coating, the protective mask is removed in acetone. The heterostructure is then wiped in acetone, degreased in tetrachloromethane and isopropyl alcohol, and fired at 130° C. for 30 minutes.

Then galvanic photolitography is carried out. Photolitography includes the following steps: applying a photoresist, applying a “contacts” pattern, exposure, development and hardening at 100° C. for 1 hour. The opposide side and ends of the sample are closed with chemically stable varnish. The gold-galvanic strengthening of the contacts is performed. The heterostructure is then wiped in acetone, degreased in tetrachloromethane and isopropyl alcohol, and fired at 130° C. for 30 minutes.

Then photolitography is performed in order to form the separating net. Photolitography includes the following steps: applying a photoresist, applying a “separating net” pattern, exposure, development and hardening at 100° C. for 1 hour. The separating net is etched in the HBr:H₂O₂ anisotropic etchant. Furthermore, etching can be performed using dry etching methods, e.g. in plasma.

Then the face side is closed with a photoresist, and the structure is glued with the face side to glass by means of picein.

Further, the structure is thinned to thickness of 200 μm by abrading the substrate, and then the structure is processed in the HCI:HNO₃:H₂O etch. Then the structure is washed to remove picein, and the photoresist is removed. The back surface is processed in plasma.

The Cr (80 Å)—Au (300 Å)—Ni (500 Å)—Au (1000 Å) continuous second contact is then coated on.

During the assembly process, the LED chip or photodiode chip is placed within a housing. The assembly process can be carried out using any known technology.

In LED chips, the selection of a side to apply the continuous contact and the point contact, and thus the choice of mounting method is made based on the following criteria: the substrate must be transparent to radiation generated in the volume of the active diode area, and the radiation output must be performed through a material with n-type conductivity, as absorption at free charge carriers in semiconductors with p-type conductivity is tens of times higher.

Considering the above criteria, in light-emitting diodes based on the first embodiment of the heterostructure, the continuous contact is applied on the substrate side, and point contacts are formed on the side of epitaxial layers. The LED chips are mounted with the substrate facing downwards. Radiation is output through epitaxial layers.

In light-emitting diodes based on the second embodiment of the heterostructure, the continuous contact is applied on the side of epitaxial layers, and point contacts are formed on the substrate side. The LED chips are mounted with the epitaxial side facing downwards. Radiation is output through the substrate.

Photodiodes are manufactured based on the second embodiment of heterostructures. The photosensitivity boundary of the diode from the long wavelength side λ_{KP} is defined by width of the forbidden gap Eg of the active area material. The short wavelength sensitivity boundary λ_{KOP} depends on the width of the forbidden gap Eg of the “wideband window”, through which light enters active area of the diode. Said “wideband window” can be formed by p-InSbP material or by the n-InAs substrate. The side through which radiation enters is determined by the required short wavelength sensitivity boundary. When the light enters from the n-InAs substrate side, λ_{KOP} is about 3 μm and the diodes are mounted with the epitaxial side facing downwards. When the diodes are mounted with the epitaxial side facing upwards, the light passes through the wideband layer p-InSbP, and λ_{KOP} is about 2 μm.

Furthermore, LED chips or photodiode chips based on the heterostructure of the present invention can be manufactured using any known methods or using any other known materials. For example, a light-emitting diode or photodiode with contacts for flip-chip mounting can be manufactured based on the heterostructure of the present invention. In the case of manufacturing a diode with contacts for flip-chip mounting, the contact coupled to the epitaxial side and the contact coupled to the substrate are placed on the bottom side, so that the upper surface of the heterostructure remains free. Manufacturing a diode according to the present invention can be performed using any methods suitable for flip-chip technology.

Furthermore, the method for manufacturing a light-emitting diode or a photodiode can include other photolithographic processes for forming elements of the light-emitting diode or photodiode, e.g. for forming a mesa.

The LED chip can have, for example, a square shape with dimensions of about 350*350 μm² with a point contact having a diameter of about 100 μm or an annular contact having a diameter of about 250 μm. The photodiode chip can have, for example, a square shape with dimensions of about 700*700 μm² with an annular contact having a diameter of about 500 μm.

Light-emitting diodes and photodiodes of the present invention operate at room temperature. Furthermore, when it is required to stabilize a certain temperature lower or higher than room temperature, diodes can comprise at least one Peltier element.

The light-emitting diode manufactured according to the present invention is operated as follows.

In the first embodiment of the heterostructure, upon application of forward voltage (positive to the substrate, negative to the active layer), the current flows through the heterostructure. Electrons are injected into the active area. High potential barrier from the side of the InSbP barrier layer limits the electron outflow from the active area. Holes from the p-type barrier layer are injected into the active area. Electrons and holes confined to the active area effectively recombinate, thus forming infrared radiation with a wavelength corresponding to the width of the forbidden gap of the active area. The radiation passes through the active layer with minimal losses and exits the light-emitting diode from the active layer side. Light-emitting diodes based on the first embodiment of the heterostructure emit at a wavelength in the range of 2.6-3.1 μm.

In the second embodiment of the heterostructure, upon application of forward voltage (positive to the barrier layer of the heterostructure, negative to the n-type substrate), the current flows through the heterostructure. Electrons are injected from the substrate into the active area. High potential barrier from the side of the InSbP barrier layer limits the electron outflow from the active area. Holes from the p-type barrier layer are injected into the active area. Electrons and holes confined to the active area effectively recombinate, thus forming infrared radiation with a wavelength corresponding to the width of the forbidden gap of the active area. The radiation passes through the substrate with minimal losses due to the fact that the substrate material does not absorb radiation in the range of 3.1-4.7 μm, and exits the light-emitting diode from the substrate side.

The photodiode manufactured according to the present invention is operated as follows.

When the photodiode is irradiated with a light flux through the n-InAs substrate or the p-InSbP layer, pairs of electric charges (free electrons and holes) are generated in the active layer InAsSb. The active layer of the photodiode comprises a depletion region of the semiconductor, which forms an integrated electric field and wherein the electron/hole pairs excited by the light are separated. Non-primary charge carriers (holes in the n-area) are pulled by the transition field and moved to the p-area of the semiconductor, where said holes constitute primary carriers. The newly formed primary charge carriers increase concentration of electrons in the n-area and lower resistance of the depletion region. Due to the movement of excess non-primary carriers formed by the light flux, a photoelectric current passing through the diode is formed. Electron/hole pairs generated in the wideband area (in the n-InAs substrate or in the p-InSbP layer) are also separated by the electric field and contribute to the photoelectric current. The long wavelength boundary of the photodiode is defined by the width of forbidden gap of the active layer of the photodiode. The short wavelength response boundary is defined by the width of the forbidden gap and by thickness of the material through which the light enters the active layer (in this case, it is defined by the width of the forbidden gap and by thickness of the n-InAs substrate or the p-InSbP layer).

The use of a “wideband window” (n-InAs substrate or p-InSbP layer) further allows to increase quantum efficiency in operation of the photodiode due to reduction in surface recombination.

It should be noted that the embodiments of the invention disclosed in the foregoing description are purely exemplary and not meant to be construed as limiting the scope of the invention. The spirit and scope of the present invention are defined solely in the following claims.

1. A heterostructure, comprising:
a substrate containing InAs,
an active area containing InAsSb and arranged on the substrate,
a barrier layer containing InSbP and arranged on the active area.

2. The heterostructure of claim 1, wherein the active area comprises a bulk layer containing InAsSb.

3. The heterostructure of claim 1, wherein the active area comprises quantum wells containing InAs and InAsSb.

4. The heterostructure of claim 1, wherein the active area comprises a strained superlattice containing GaInAs and InAsSb.

5. A method for manufacturing the heterostructure of claim 1, comprising the steps of:
depositing an active area containing InAsSb on a substrate containing InAs by means of vapor-phase epitaxy,
depositing a barrier layer containing InSbP on the active area by means of vapor-phase epitaxy,
wherein tert-butylarsine is used as the source of arsenic, and tert-butylphosphine is used as the source of phosphorus.

6. A light-emitting diode, comprising
at least one LED chip having at least two contacts, wherein the LED chip is formed based on the heterostructure comprising
a substrate containing InAs,
an active area containing InAsSb and arranged on the substrate,
a barrier layer containing InSbP and arranged on the active area.

7. The light-emitting diode of claim 6, wherein the LED chip has a first contact arranged on the substrate side and a second contact arranged on the active layer side.

8. The light-emitting diode of claim 6, wherein the LED chip comprises at least two contacts arranged on the side of the light-emitting diode opposite to the emitting side of the light-emitting diode.

9. The light-emitting diode of claim 6, comprising a first contact arranged on the barrier layer side and a second contact arranged on the substrate side.

10. The light-emitting diode of claim 6, comprising a first contact, which is continuous, and a second contact which is formed with partial surface covering.

11. The light-emitting diode of claim 6, wherein at least one contact has a circular or annular shape.

12. The light-emitting diode of claim 6, wherein the contacts comprise a four-layer Cr/Au/Ni/Au system.

13. A method for manufacturing the light-emitting diode of claim 6, comprising the steps of:
providing a heterostructure comprising a substrate containing InAs, an active area containing InAsSb and arranged on the substrate, and a barrier layer containing InSbP and arranged on the active area;
arranging at least two contacts;
dividing the heterostructure with contacts formed thereon, thus forming LED chips.

14. The method for manufacturing of claim 13, wherein the contacts are arranged on the opposite sides of the heterostructure.

15. The method for manufacturing of claim 13, wherein at least two contacts are formed on the substrate side or at least two contacts are formed on the barrier layer side.

16. A photodiode, comprising at least one photodiode chip having at least two contacts, wherein the photodiode chip is formed based on the heterostructure comprising
a substrate containing InAs,
an active area containing InAsSb and arranged on the substrate,
a barrier layer containing InSbP and arranged on the active area.

17. The photodiode of claim 16, comprising two contacts, one of which is arranged on the substrate side and the other is arranged on the barrier layer side.

18. The photodiode of claim 16, comprising two contacts, wherein one of the contacts is formed with partial surface covering, and the other contact is continuous.

19. The photodiode of claim 16, comprising at least two contacts, wherein one of the contacts has an annular shape.

20. The photodiode of claim 16, comprising at least two contacts, wherein the contacts comprise a four-layer Cr/Au/Ni/Au system.

21. The photodiode of claim 16 comprising at least two contacts arranged on the side of the photodiode opposite to the radiation-receiving side of the photodiode.

22. A method for manufacturing the photodiode of claim 16, comprising the steps of:
providing a heterostructure comprising
a substrate containing InAs,
an active area containing InAsSb and arranged on the substrate,
a barrier layer containing InSbP and arranged on the active area, arranging at least two contacts;
dividing the heterostructure with contacts formed thereon, thus forming photodiode chips.

23. The method for manufacturing of claim 22, wherein the two contacts are formed on the opposite sides of the heterostructure.

24. The method for manufacturing a photodiode of claim 22, wherein at least two contacts are formed on the barrier layer side or at least two contacts are formed on the substrate side.

25. A heterostructure, comprising:
a substrate containing InAs,
a barrier layer containing InSbP and arranged on the substrate,
an active layer containing InAsSbP and arranged on the barrier layer.

26. A method for manufacturing the heterostructure of claim 25, comprising the steps of:
depositing a barrier layer containing InSbP on a substrate containing InAs by means of vapor-phase epitaxy,
depositing an active layer containing InAsSbP on the barrier layer by means of vapor-phase epitaxy,
wherein tert-butylarsine is used as the source of arsenic, and tert-butylphosphine is used as the source of phosphorus.

27. A light-emitting diode for producing radiation in middle infrared band, comprising
at least one LED chip having at least two contacts, wherein the LED chip is formed based on the heterostructure comprising
a substrate containing InAs,
a barrier layer containing InSbP and arranged on the substrate, and
an active layer containing InAsSbP and arranged on the barrier layer.

28. The light-emitting diode of claim 27, wherein the LED chip comprises a first contact arranged on the substrate side and a second contact arranged on the active layer side.

29. The light-emitting diode of claim 27, wherein the first contact is continuous, and the second contact is formed with partial surface covering.

30. The light-emitting diode of claim 27, wherein the second contact has a circular or annular shape.

31. The light-emitting diode of claim 27, wherein the contacts comprise a four-layer Cr/Au/Ni/Au system.

32. The light-emitting diode of claim 27, comprising at least two contacts arranged on the side of the light-emitting diode opposite to the emitting side of the light-emitting diode.

33. A method for manufacturing a light-emitting diode of claim 27, comprising the steps of:
providing a heterostructure comprising a substrate containing InAs, a barrier layer containing InSbP and arranged on the substrate, and an active layer containing InAsSbP and arranged on the barrier layer;
arranging at least two contacts;
dividing the heterostructure with contacts formed thereon, thus forming LED chips.

34. The method for manufacturing of claim 33, wherein the contacts are arranged on the opposite sides of the heterostructure.

35. A method for manufacturing of claim 33, wherein at least two contacts are formed on the substrate side.

36. A method for manufacturing of claim 33, wherein at least two contacts are formed on the barrier layer side.
